(19) United States
(12) Patent Application Publication
(10) Pub. No.: US 2001/0004246 A1
(43) Pub. Date: Jun. 21, 2001

(54) Electric device, electric device testing apparatus, and electric device testing method thereof

(76) Inventor: Koji Asami, Tokyo (JP)

Correspondence Address: Pillsbury & Winthrop LLP, Intellectual Property Group, Ninth Floor, 1100 New York Avenue, NW, Washington, DC, 20005-3918, US

(21) Appl. No.: 09/765,404

(22) Filed: Jan. 22, 2001

Related U.S. Application Data
(63) Continuation of application No. PCT/JP00/04627, filed on Jul. 11, 2000.

(30) Foreign Application Priority Data
Jul. 13, 1999 (JP) H11-198605

(51) Int. Cl. H03M 1/10

(52) U.S. Cl. 341/120

(57) ABSTRACT

An electric device 100 has a conversion unit 102, and a Σ Δ modulator 106 which functions as a D/A converter is included therein. The electric device 100 inputs an indication signal 40 for requesting a shift to test mode. The electric device testing apparatus 10 has an analog test pattern generator 16 for generating a pattern for testing an analog unit 108 of the electric device 100. The pattern generated herein is a digital signal. Consequently, after it is converted to an analog signal by the Σ Δ modulator 106, a testing process is performed.

This is a continuation application of PCT/JP00/04627 filed on Jul. 11, 2000, the contents of which and the contents of a Japanese patent application, H11-198605 filed on Jul. 13, 1999, are incorporated herein by reference.

### BACKGROUND OF THE INVENTION

1. Field of the Invention

This invention relates to an electric device, an electric device testing apparatus, and an electric device testing method. In particular, this invention relates to an electric device for achieving a predetermined function by inputting and outputting a signal, an electric device testing apparatus for testing the function thereof, and an electric device testing method capable of being used by the apparatus thereof. Furthermore, the present application relates to the following Japanese Patent application. For any country where it is permitted to include documents by reference, the contents described in the following application are incorporated by reference in the present invention, and thus they shall be a part of the description of the present application.

Toku-Gan-Hei 11-198605 Filing data H11.7.13

2. Description of the Related Art

Conventionally, an individual device, for example, an LSI or a device referred to as LSI in general, may have a function for processing both a digital signal and an analog signal. When such a digital/analog hybrid device is tested, in general, a conventional pattern generator is used for a functional part (hereinafter “digital unit”) in relation to a digital signal, and an optional waveform generator is used for a functional part (hereinafter “analog unit”) in relation to an analog signal. As current semiconductor technology progresses, the speed of the digital/analog hybrid device used for processing the signal has increased significantly. A high standard of performance is therefore required from the optional waveform generator and the pattern generator thereof.

The optional waveform generator generates an analog signal in general. The conventional digital device requires an optional waveform generator because it does not have an analog unit like the digital/analog hybrid device. The size of the electric device testing apparatus is therefore large and is subsequently expensive. Furthermore, in the case where it is required to synchronize an analog unit test with a digital unit test, it becomes difficult to process as the speed of the signal becomes higher.

The present invention is a result of the above mentioned aspects, the purpose thereof being to provide the electric device testing technology capable of simplifying the structure of testing the electric device. Furthermore, the electric device suitable to this kind of testing is additionally provided. The purpose thereof is achieved by a combination of characteristics detailed in independent claims of the scope of claims. Furthermore, dependent claims define exemplified and preferred embodiments of the present invention.

### DISCLOSURE OF INVENTION

An electric device of the present invention includes an analog unit that operates by receiving an analog signal, a conversion unit for converting a digital signal, which is input from the outside, to an analog signal, and a mode assignment pin for assigning an operation mode of the electric device. Here, in the event that an indication signal, which indicates that the above-mentioned electric device is set to test mode, is applied to the above-mentioned mode assignment pin, an analog signal that is obtained by the above-mentioned conversion unit is applied to the above-mentioned analog unit.

The above-mentioned conversion unit may include a circuit that generates a reference clock that becomes a base clock of a sampling clock which is used in the above-mentioned conversion unit. The electric device thereof may include a clock output pin for outputting the above-mentioned reference clock to the outside, and a clock input pin for inputting the above-mentioned sampling clock from the outside.

Furthermore, a conversion signal output pin for outputting a signal may be included, which is obtained by the above-mentioned conversion unit, to the outside and an analog signal input pin for inputting an analog signal from the outside. Furthermore, an analog signal, which is applied to the above-mentioned analog signal input pin, may be applied to the above-mentioned analog unit, when an indication signal, which indicates that the above-mentioned electric device is set to test mode, is applied.

The electric device testing apparatus of the present invention includes a test mode setting circuit for generating an indication signal for setting the electric device as a test mode; and an analog test pattern generator for generating a test pattern as a digital signal, which is to test an analog unit in the electric device, at least when the indication signal is generated, in which the test pattern is applied to the electric device using a digital signal as it is.

The electric device test method of the present invention includes a shifting stage of shifting the electric device to test mode; a generating stage of generating a test pattern, which is to test an analog unit in the electric device, as a digital signal; a conversion process stage of converting, in the electric device, the digital signal to an analog signal; and an applying stage of applying, in the test mode, the analog signal to an analog unit of the electric device.

Here, the summary of the invention in the foregoing does not list all of the characteristics necessary for the present invention. Sub-combinations of such characteristics shall in fact be the present invention.

### BRIEF DESCRIPTION OF THE DRAWINGS

FIG. 1 is a block diagram of an electric device and an electric device testing apparatus in relation to the preferred embodiment.

FIG. 2 is a processing flow chart in which the electric device testing apparatus in relation to the preferred embodiment tests the electric device in relation to the preferred embodiment in the same way.

### OPTIMAL MODE FOR CARRYING OUT THE INVENTION

Here, the present invention is explained using the preferred embodiment of the present invention. The preferred embodiment of the present invention hereinafter, however, does not limit the invention detailed in the scope of claims. All of the features and the combinations thereof described in the preferred embodiments are not necessarily essential to the invention.

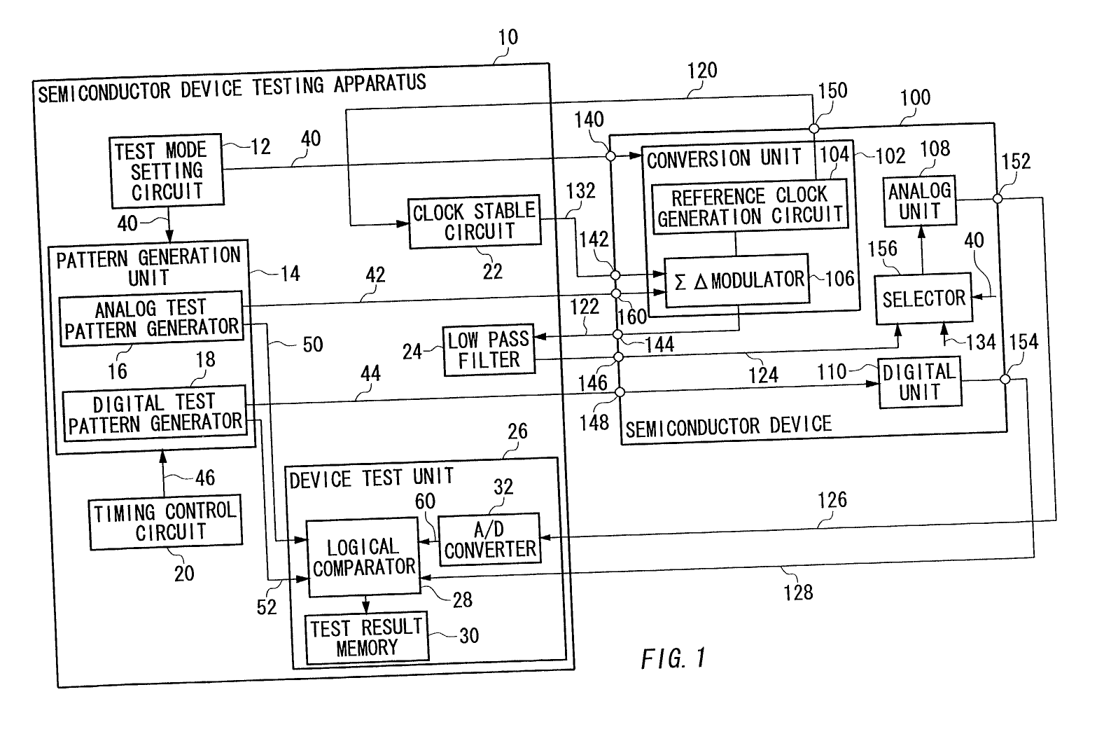

FIG. 1 is a block diagram of an electric device and an electric device testing apparatus in relation to the preferred embodiment. An electric device testing apparatus 10 tests an analog-digital mixture type electric device 100. For example, the electric device 100 may be a semiconductor device.

The electric device testing apparatus 10 has a test mode setting circuit 12 for generating an indication signal 40 for indicating that the electric device 100 is set to test mode, an analog test pattern generator 16 for generating a test pattern, which is used for testing an analog unit 108 of the electric device 100, as a digital signal, and a digital test pattern generator 18 for generating a test pattern for testing a digital unit 110 in the same way.

An analog test pattern 42 generated in the analog test pattern generator 16 is passed to a conversion unit 102 by an analog test pattern input pin 160 of the electric device 100. In addition, the analog test pattern generator 16 generates an expected value signal 50 which should be output from the analog unit 108, and outputs to a logical comparator 28 of a device test unit 26.

A digital test pattern 44 generated in the digital test pattern generator 18 is passed to the digital unit 110 by a digital test pattern input pin 148 of the digital unit 110. The digital test pattern generator 18, in addition, generates an expected value signal 52 which should be output from the digital unit 110 and passes it to the logical comparator 28. The analog test pattern generator 16 and the digital test pattern generator 18 are included in a pattern generation unit 14.

The indication signal 40 is additionally input to the pattern generation unit 14. When the electric device 100 is in the test mode the test pattern is allowed to be generated. Here, all of the analog test pattern 42, the expected value signal 50 that is output from the analog unit 108, and the expected value signal 52 that is output from the digital unit 110 are digital signals. Although the analog test pattern 42 is a digital signal, it is passed directly to the electric device 100. A timing control circuit 20 gives a timing signal 46, such as a clock, to the analog test pattern generator 16 and the digital test pattern generator 18. A function to synchronize the analog test pattern generator 16 with the digital test pattern generator 18 is also included.

A clock stabilization circuit 22 includes PLL (Phase Locked Loop), inputs a reference clock 120, which is described hereinafter, that is output from the electric device 100, and generates a sampling clock 132 by eliminating a jitter element of the clock thereof. The sampling clock 132 is input to the conversion unit 102 of the electric device 100 by way of the sampling clock 132.

A low pass filter 24 inputs an output signal 122 of a Σ Δ modulator 106 by way of a conversion signal output pin 144, performs filtering thereto, and generates an analog test signal 124. The low pass filter 24 is composed of circuit parts in general, so that it is possible to adjust it outside the electric device 100. The analog test signal 124 is input to a selector 156 by way of an analog signal input pin 146 of the electric device 100.

The device test unit 26 includes the logical comparator 28, an A/D converter 32, and a test result memory 30. An output 126 of the analog unit 108 of the electric device 100 is input to the A/D converter 32 by way of an analog test result output pin 152. An output 60 of the A/D converter 32 is passed to the logical comparator 28. An output 128 of the digital unit 110 of the electric device 100 is given to the logical comparator 28 by the digital test result output pin 154.

The logical comparator 28 compares the output 128 of the digital unit 110 with the expected value signal 52 which should be output from the digital unit 110. If the result thereof indicates disagreement, the test result memory 30 memorizes that there is something defective. Furthermore, the logical comparator 28 compares the output 126 of the analog unit 108 with the expected value signal 50 which should be output from the analog unit 108. If the result thereof indicates disagreement, it is memorized in the test result memory 30 in the same way as if something is defective.

The electric device 100 includes the analog unit 108, digital unit 110, the conversion unit 102 for converting a digital signal input from the outside, which is the analog test pattern 42 herein, to an analog signal, and a mode assignment pin 140 for assigning an operation mode of the electric device. The indication signal 40 explained in the foregoing is applied to the mode assignment pin 140.

The electric device 100 further includes the selector 156 that selects one signal of an analog signal 134, which should be passed to the analog unit 108 when it is operated in a normal status except the test mode, having a normal mode and the analog test signal 124. The indication signal 40 is input to the selector 156, and the selector 156 selects the analog test signal 124 during the test mode and the analog signal 134 having the normal mode during the normal operation on the other hand respectively, and applies them to the analog unit 108.

The conversion unit 102 includes a reference clock generation circuit 104 and the Σ Δ modulator 106. The Σ Δ modulator 106 functions as a D/A converter by a combination of the subsequent low pass filter 24 therewith. Since it is possible to make and use the highly qualified Σ Δ modulator 106 by a conventional logical circuit, it is suitable to for installment in the electric device 100.

The reference clock 120 output from the reference clock generation circuit 104 is passed to a clock stable circuit 22 by way of a clock output pin 150. The reference clock 120 becomes a basic element to the sampling clock 132 that is used in the Σ Δ modulator 106. For the reference clock 120, an optimal frequency is determined by a feature of the Σ Δ modulator 106. Thus, in accordance with the present invention, both the reference clock generation circuit 104 and the Σ Δ modulator 106 are included. Knowing that the clock stable circuit 22 is PLL, the frequency of the reference clock 120 and the sampling clock 132 can be represented as ratios of whole numbers.

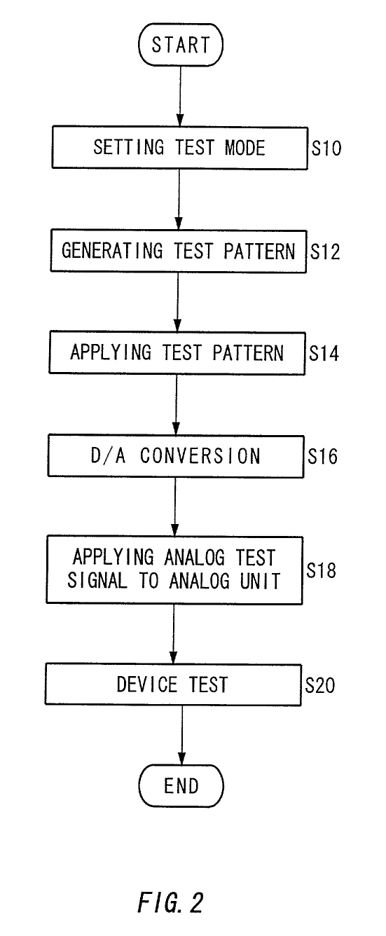

FIG. 2 is a flow chart of a test process of the electric device 100 by the electric device testing apparatus 10. Firstly, the test mode is set in the electric device 100 by the test mode setting circuit 12 (S10). That is to say, the electric device 100 is shifted to the test mode by the indication signal 40. The pattern generation unit 14 is activated by the indication signal 40, and the analog test pattern 42 and the digital test pattern 44 are activated by the analog test pattern generator 16 and the digital test pattern generator 18 respectively (S12). They are synchronized with each other by the timing control circuit 20 to generate the test pattern from the analog test pattern generator 16 and the digital test pattern generator 18. The analog test pattern 42 and the digital test pattern 44 are applied to the Σ Δ modulator 106 of the conversion unit 102 and the digital unit 110 respectively (S14).

The operation of the conversion unit 102 is also allowed by the indication signal 40. The reference clock 120 is output from the reference clock generation circuit 104 and input to the clock stable circuit 22. The sampling clock 132, having less jitters, is output from the clock stable circuit 22, and then input to the Σ Δ modulator 106. The Σ Δ modulator 106 modulates the analog test pattern 42 based on the sampling clock 132. The output signal 122 of the Σ Δ modulator 106 is input to the low pass filter 24, and a D/A conversion is completed by way of a filtering process (S16).

The analog test signal 124 obtained by the D/A conversion is input to the selector 156. The selector 40 selects the analog test signal 124 by the indication signal 40, and applies it to the analog unit 108 (S18).

The analog unit 108 performs specified functions in accordance with the analog test signal 124. The output 126, which is obtained as a result thereof, of the analog unit 108 is input to the A/D converter 32 of the device test unit 26 and converted to the digital signal at this stage.

The output 60 of the A/D converter 32 is compared with the expected value signal 50, which should be output from the analog unit 108, in the logical comparator 28. On the other hand, the output 128 of the digital unit 110 is compared with the expected value signal 52, which should be output from the digital unit 110, in the logical comparator 28. Based on these comparison results, testing the device (S20) is performed, and a test result or information indicating failure is stored in the test result memory 30. Thus, a series of test processing is performed.

In the foregoing, although the preferred embodiment has been explained, the technical scope of the present invention is not limited to the description thereof.

As the first modified embodiment, a device for performing D/A conversion is not limited to the Σ Δ modulator 106 in the conversion unit 102. It is also possible to use another D/A converter.

As the second modified embodiment, it is possible to generate the sampling clock 132 using a clock other than the reference clock 120. For example, when the electric device 100 uses any type of clock, it is possible to utilize the clocks thereof by dividing the frequency thereof, etc.

As the third modified embodiment, the electric device 100 is not limited to a digital/analog hybrid device, but may purely be an analog device.

It is possible for persons having ordinary skill in the art to add various modifications and improvements to the preferred embodiment other than the foregoing. It is obvious according to the details of the scope of claims that the embodiments to which such modifications or improvements thereof are added are included in the scope of the present invention.

Industrial Applicability

In accordance with the preferred embodiment, it is possible to test an electric device using a relatively simple structure.

What is claimed is:

1. An electric device for processing a signal, comprising:
an analog unit for functioning by receiving an analog signal;
a conversion unit for converting a digital signal being input from an outside to an analog signal; and
a mode assignment pin for assigning an operation mode of said electric device,
wherein, an analog signal obtained by said conversion unit is applied to said analog unit when an indication signal for setting said electric device as a test mode is applied to said mode assignment pin.

2. An electric device according to claim 1, wherein said conversion unit includes a Σ Δ modulator.

3. An electric device according to claim 1 or 2, wherein said conversion unit includes a circuit for generating a reference clock as a base clock of a sampling clock which is used in said conversion unit, and said electric device includes:
a clock output pin for outputting the reference clock to an outside; and
a clock input pin for inputting the sampling clock from the outside.

4. An electric device according to any one of claims 1-3, further comprising:
a conversion signal output pin for outputting a signal obtained in said conversion unit to the outside; and
an analog signal input pin for inputting an analog signal from the outside,
wherein, an analog signal applied to said analog signal input pin is applied to said analog unit when an indication signal for setting said electric device as a test mode is applied to said mode assignment pin.

5. An electric device testing apparatus for testing an electric device, comprising:
a test mode setting circuit for generating an indication signal for setting said electric device as a test mode; and
an analog test pattern generator for generating a test pattern as a digital signal, which is to test an analog unit in said electric device, at least when the indication signal is generated,
wherein the test pattern is applied to said electric device using a digital signal as it is.

6. An electric device testing apparatus according to claim 5, further comprising:
a circuit for stabling a clock which should be input to said electric device.

7. An electric device testing apparatus according to claim 5 or 6, further comprising:
a digital test pattern generator for generating a test pattern for testing a digital unit in said electric device; and
a timing control circuit for synchronizing said analog test pattern generator with said digital test pattern generator.

8. An electric device testing apparatus according to any one of claims 5-7, further comprising:
a device test unit for testing said electric device by comparing an expected value signal with a signal output from said electric device.

9. An electric device test method for testing an electric device, comprising:
a shifting stage of shifting said electric device to a test mode;
a generating stage of generating a test pattern, which is to test an analog unit in said electric device, as a digital signal;
a conversion process stage of converting, in said electric device, said digital signal to an analog signal; and
an applying stage of applying, in said test mode, the analog signal to an analog unit of said electric device.

10. An electric device test method according to claim 9, further comprising:
a generation stage of generating a test pattern for testing a digital unit of said electric device by synchronizing with generation of a test pattern based on said analog unit.

11. An electric device test method according to claim 9 or 10, comprising the steps of:
outputting a predetermined reference clock from said electric device;
performing a stabilizing process to the reference clock; and
inputting the reference clock in which said stabilizing process is performed to said electric device,
wherein said conversion process stage uses said reference clock in which said stabilizing process is performed as a sampling clock.
